(19) United States
(12) Patent Application Publication
(10) Pub. No.: US 2007/0148804 A1
(43) Pub. Date: Jun. 28, 2007

(54) Method of making a multilayered device with ultra-thin freestanding metallic membranes using a peel off process

(75) Inventors: Pavel Ustyuzhanin, Jerusalem (IL); Yisrael Sundick, Jerusalem (IL); Gil Geva-mittelberg, Rishon-Lezion (IL)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 11/321,924

(22) Filed: Dec. 28, 2005

(51) Int. Cl. H01L 21/00; H01L 21/44; H01L 21/4763

(52) U.S. Cl. 438/50; 438/53; 438/460; 438/464; 438/619; 438/670

(57) ABSTRACT

A micro electromechanical device includes a substrate having stacked films. Each of the films includes a first layer and a second layer. The second layer is metal of a predetermined thickness. The stacked films are formed by electroplating the second layer on the first layer and lifting off a third layer, a fourth layer and a fifth layer.

### BACKGROUND

1. Field

The embodiments relate to a method, micro electromechanical device and system using a lift off process, and more particularly to using the lift off process to form metal free standing membranes of a predetermined desired thickness.

2. Description of the Related Art

Multilayered ultra-thin metallic membranes with area of several millimeters and fixed thickness of less then hundred nanometers are applied currently as essential device components for transition radiation laser optics. Although, techniques for one layered free-standing micromachined membranes fabrication on silicon wafer exist, the fabrication of freestanding multilayered structures suffers from complex processing issues. With the traditional micromachining build up technique, when the stack of membranes is created and then the diaphragms supported material is removed, the major issue is qualitative release of the sacrificial supported material. Wet etch or dilution are rather lengthy processes and usually cause fatal membranes sticking, while dry etch damages the material of membrane due to sputtering.

FIG. 1 illustrates a typical silicon build up technique with membranes attached to the pillars after sacrificial layer release.

### BRIEF DESCRIPTION OF THE DRAWINGS

The embodiments are illustrated by way of example, and not by way of limitation, in the figures of the accompanying drawings and in which like reference numerals refer to similar elements and in which:

FIG. 1 is a cross sectional view of a traditional micromachined membrane;

FIG. 2 is a perspective view of a protective layer added to a wafer according to an embodiment;

FIG. 3 is a cross sectional view showing the resist profile of the wafer of FIG. 2 according to an embodiment;

FIG. 4 is a perspective view showing the wafer in the combination of FIG. 3 as having been electroplated according to an embodiment;

FIG. 5 is a cross sectional top plan view showing the embodiment of FIG. 4 before top protective layer deposition according to an embodiment;

FIG. 6 is a perspective view showing the combination of FIG. 4 showing a peel-off process according to an embodiment;

FIG. 7 is a perspective view showing the electroplated membrane after a peel-off process according to an embodiment;

FIG. 8 is a top plan view of a multiple formed film from a peel-off process according to an embodiment;

FIG. 9 is a is a perspective view of diced films stacked according to an embodiment;

FIG. 10 illustrates the stack of FIG. 9 inserted into a mechanical device for alignment.

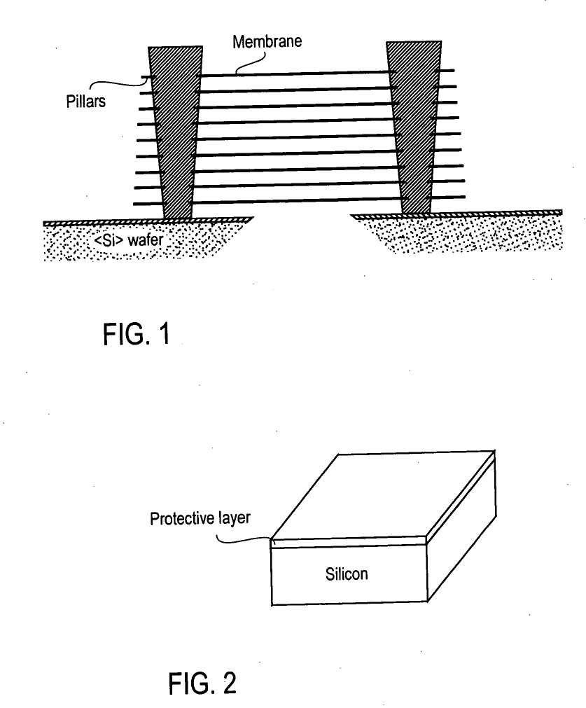

### DETAILED DESCRIPTION

The embodiments discussed herein generally relate to a method and micro electromechanical device for non-limited stack of ultra-thin metallic membranes with fixed distances between membranes. Referring to the figures, exemplary embodiments will now be described. The exemplary embodiments are provided to illustrate the embodiments and should not be construed as limiting the scope of the embodiments.

Various operations will be described as multiple discrete operations, in turn, in a manner that is most helpful in understanding the present invention, however, the order of description should not be construed as to imply that these operations are necessarily order dependent. In particular, these operations need not be performed in the order of presentation.

FIG. 2 illustrates a beginning of a process for providing an electro-mechanical device where a protective layer added to an oxidized silicon wafer. The nature of the silicon oxide does not significantly influence the properties of the final electromechanical device (i.e., the same properties were found in case of low pressure chemical vapor deposited (LPCVD) and plasma enhanced chemically vapor deposited (PECVD) oxides). In one embodiment the protective layer is an alkaline protective polymer, such as Protek™. In one embodiment the alkaline protective polymer is spun on the oxidized surface of the silicon wafer to get the thickness of about 8 nm and then cured up to final hardening.

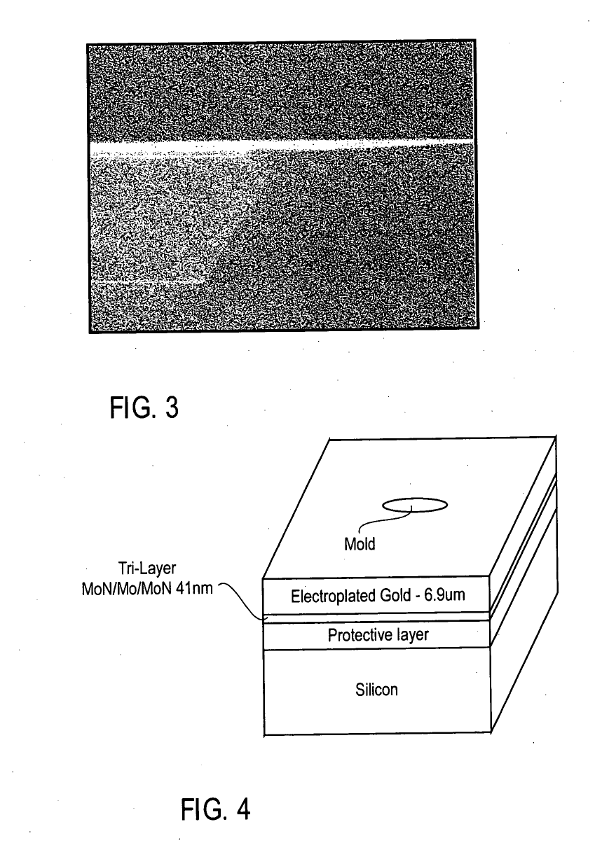

Next the membrane of the required metal with a desired (i.e., the metal membrane has a predetermined thickness) thickness is sputtered onto the cured protective layer. The metal of the diaphragm itself is protected with patterned resist using a “lift off.” This is essential for further sputtering of the seed layer for electroplating. The profile of the patterned resist is shown in FIG. 3.

Following a seed layer for electroplating is sputtered on to prepare for a “peel off” treatment surface. In one embodiment, the seed layer is single layer of Au. In one embodiment, the thickness of the tri-layer ranges from 15 nm to 100 nm for optical devices. In another embodiment, the thickness of the tri-layer can exceed 100 nm. Next the patterned resist, which was used for membrane protection, is removed by solvent together with the sputtered on its surface seed layer. In one embodiment, the solvent used is acetone. In another embodiment the commercially produced solvent PRS3000 from Baker Scientific is used.

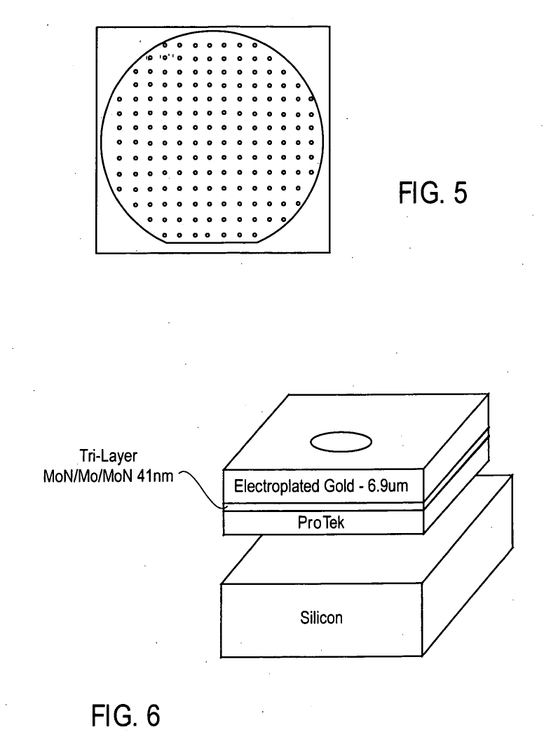

As illustrated in FIG. 4, a thick mold resist is patterned with the same or similar reticle as for the “peel off” process to protect the membrane during electroplating. The metal, aimed to determine the distance between membranes, is electroplated on top of the seed layer, while the membrane itself remains protected with mold resist. That is, the metal layer determines a distance between each wafer in the soon to be stacked plurality of films. In one embodiment, the electroplated metal is Au (i.e., gold). In another embodiment, other metals can be used, such as Pt, Ni, etc. In yet another embodiment, a polymer material can be used. FIG. 5 illustrates a partially manufactured sputtered on metal tri-layer MoN/Mo/MoN membrane under electroplated Au (e.g., 6.9 μm thickness) with a sputtered gold seed layer (e.g., 350 Å thick).

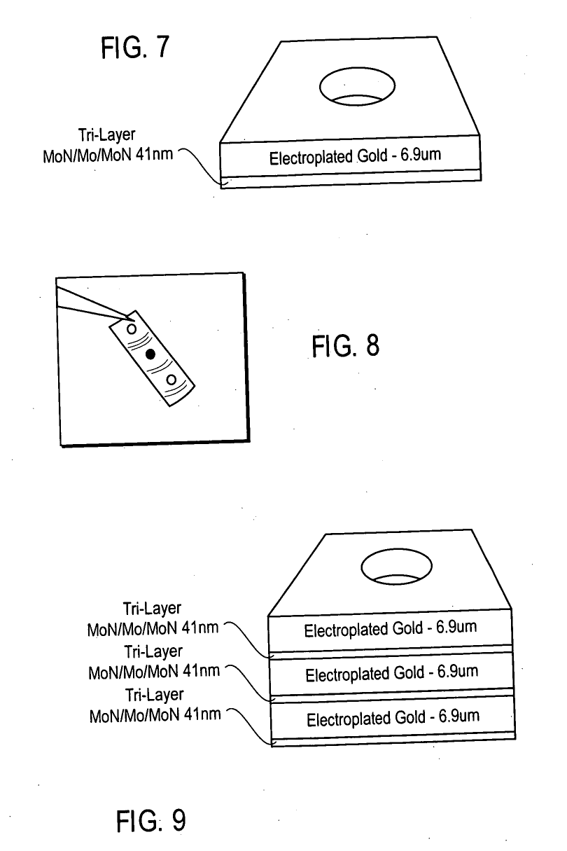

The top surface of the wafer is protected with a second layer of the spun alkaline protective polymer before the wafer is diced into a plurality of wafers. FIG. 6 illustrates the separation or “peel off” of the film from the silicon wafer. In one embodiment the silicon wafer is delaminated from the other layers by using KOH allowing the layers to be separated or peeled-off one another. The protective polymer layer is then cleaned in a solvent(s) to dissolve the protective polymer layer leaving the tri-layer and the electroplated metal as illustrated in the diced film in FIG. 7. This treating of the wafers with liquid solvent(s) delaminates the second protective polymer layer from the wafer.

FIG. 8 illustrates a cleaned wafer ready for dicing. The dicing of the film creates single multi-layered dies. In one embodiment the dies are treated with 20% water KOH (potassium hydroxide) solution in the temperature range of 20-45° C. up to the full delamination of the first (i.e., bottom) protective polymer layer from the oxidized silicon surface. This temperature range is used as higher temperatures can cause the second (i.e., top) protective polymer layer delamination and damage the membrane surface.

Delaminated films are then cleaned with liquid solvents. In one embodiment acetone and isopropyl alcohol (IPA) are used. In another embodiment, alternative solutions are used. The films are then dried under room temperature as illustrated in FIG. 8.

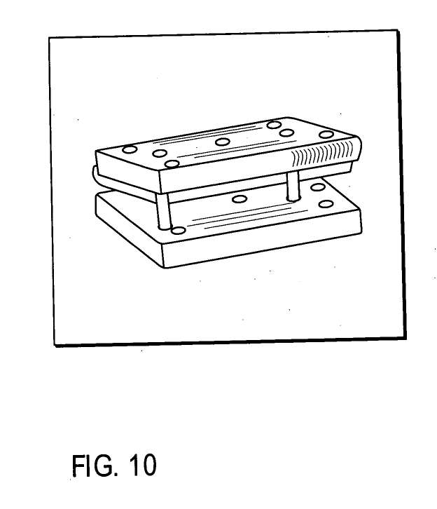

The prepared films are then stacked as illustrated in FIG. 9. It should be noted that while FIG. 9 illustrates a stack of three films, any amount of films can be stacked as desired. The stacked films are then assembled in a stack inside a mechanical fixture as illustrated in FIG. 10. The mechanical fixture is sized as desired for the amount of films desired to be stacked. The mechanical fixture ensures the stacked films are aligned properly. The tri-layer membrane spaces the stacked metal films from one another.

The above embodiments allow creation of a non-limited stack of ultra-thin freestanding metallic membranes (less than 100 nm) with a fixed distance between each membrane. The purity of the layers is controlled for each membrane by using optical and electron microscopes before assembling. The independent cleaning and drying of the layers prevent the membranes from sticking after their assembly in a single multilayered device. In one embodiment the micro-electromechanical (MEM) devices including the stacked films are used as a component for transition radiation laser optics. The fabrication of the stacked metal films reduces the traditional complex processing issues and qualitative release of the traditional sacrificial supported material. And, the problem of membranes sticking to one another is eliminated.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances “an embodiment,” “one embodiment,” or “some embodiments” are not necessarily all referring to the same embodiments. If the specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

What is claimed is:

1. A method of providing a micro electromechanical device comprising:
providing a wafer;
depositing a first protective polymer layer on the wafer;
sputtering a metal membrane on the first protective polymer layer;
applying a metal patterned resist layer using a lift-off process to the metal membrane;
applying a seed layer to the metal patterned resist layer;
removing a portion of the metal patterned resist layer and the seed layer;
patterning a mold resist layer on the metal membrane, and electroplating a remaining portion of the seed layer with a metal layer.

2. The method of claim 1, further comprising:
applying a second protective polymer layer on top of the wafer;
dicing the wafer into a plurality of wafers;
treating the plurality wafers with a liquid;
cleaning a plurality of films that are delaminated with a solvent, and stacking the plurality of films.

3. The method of claim 2, wherein the metal layer determines a distance between each wafer in the stacked plurality of films.

4. The method of claim 2, wherein the stacked plurality of films are placed in a mechanical fixture for alignment.

5. The method of claim 2, wherein the treating the plurality wafers with the liquid is performed in a temperature range between 20° C. to 45° C.

6. The method of claim 4, wherein the treating the plurality wafers with the liquid delaminates the second protective polymer layer from the wafer.

7. The method of claim 1, wherein the metal membrane is of a predetermined thickness.

8. The method of claim 1, wherein the metal layer is gold.

9. The method of claim 1, wherein the liquid is a potassium hydroxide solution.

10. The method of claim 1, wherein the metal membrane is a tri-layer of MoN, Mo and MoN.

11. The method of claim 1, wherein the seed layer is a bi-layer of Ti and Au.

12. A micro electromechanical device comprising:
a substrate comprising a plurality of stacked films, each of the films of the plurality of stacked films includes a first layer and a second layer, the second layer is metal of a predetermined thickness;
wherein the plurality of stacked films are formed by electroplating the second layer on the first layer and lifting off a third layer, a fourth layer and a fifth layer.

13. The micro electromechanical device of claim 12, wherein the first layer is made of MoN and Mo.

14. The micro electromechanical device of claim 12, wherein third layer is silicon, the fourth layer is a first protective polymer layer, and the fifth layer is a second protective polymer layer.

15. The micro electromechanical device of claim 12, wherein a first solvent operates to remove the fourth layer and the fifth layer.

16. The micro electromechanical device of claim 12, wherein a second solvent operates to remove the fourth layer and the fifth layer.

17. The micro electromechanical device of claim 12, further comprising a mechanical device, wherein the plurality of stacked films are disposed within the mechanical device.

18. A micro electromechanical system comprising:
a plurality of stacked dies, each of the dies of the plurality of stacked dies includes a first layer, a second layer and a seed layer, the first layer is a membrane, the second layer is a metal of a predetermined thickness and is electroplated on the seed layer;
wherein the plurality of stacked dies are formed by lifting off protective layers and delaminating a previously coupled substrate from the first layer; and
a housing, the housing operates to align the plurality of stacked dies;

19. The system of claim 18, wherein the substrate is oxidized silicon.

20. The system of claim 18, wherein the protective layers are dissolved off.

21. The system of claim 18, wherein the metal layer is gold.

22. The system of claim 18, wherein the plurality of stacked dies are from a single wafer that is diced to form the plurality of stacked dies.
